(19) United States
(12) Patent Application Publication
(10) Pub. No.: US 2023/0250555 A1
(43) Pub. Date: Aug. 10, 2023

(54) GROUP 13 ELEMENT NITRIDE CRYSTAL LAYER GROWTH METHOD, NITRIDE SEMICONDUCTOR INGOT AND SPUTTERING TARGET

(71) Applicant: NGK INSULATORS, LTD., Nagoya-shi (JP)

(72) Inventors: Yoshitaka KURAOKA, Okazaki-City (JP); Kentaro NONAKA, Gifu-City (JP)

(21) Appl. No.: 18/300,774

(22) Filed: Apr. 14, 2023

Related U.S. Application Data
(63) Continuation of application No. PCT/JP2021/026080, filed on Jul. 12, 2021.

(30) Foreign Application Priority Data
Oct. 15, 2020 (JP) 2020-173913

(51) Int. Cl. C30B 29/38; C30B 23/02; C30B 19/04

(52) U.S. Cl. CPC C30B 29/38; C30B 19/04; C30B 23/02

(57) ABSTRACT

It is provided a method of growing a group 13 nitride crystal layer, on an underlying substrate including a seed crystal layer composed of a group 13 nitride. The underlying substrate is immersed in a melt containing a flux to grow a group 13 nitride crystal layer two-dimensionally on a nitrogen polar surface of the seed crystal layer by flux method.

### CROSS-REFERENCE TO RELATED APPLICATIONS

This application is a continuation application of PCT/JP2021/026080, filed Jul. 12, 2021, which claims priority to Japanese Application No. JP2020-173913 filed on Oct. 15, 2020, the entire contents all of which are incorporated hereby by reference.

### TECHNICAL FIELD

The present invention is related to a method of growing a group 13 nitride crystal layer, a nitride semiconductor ingot and sputtering target.

### BACKGROUND ARTS

As a nitride semiconductor has a wide band gap of direct transition type, high insulation breakdown electric field and high saturation electron velocity, it has drawn attention as a light emitting device such as an LED or LD and as a semiconductor material for an electronic device of high frequency and high power.

It has been known that gallium nitride crystal can be grown in the direction of -c axis on an inner wall surface of a crucible by so-called flux method (patent document 1; Japanese patent publication No. 2005-206415A). According to the method, for promoting the N-plane growth of gallium nitride crystal on the inner wall surface of the crucible, an element such as Mn, Fe, Cr, Co, Ni is added into the melt. It could be, however, realized the growth of pillar-shaped crystals having lengths of about 1.5 mm according to the inventive example.

Further, it has been proposed to produce an ingot by growing a thick film of gallium nitride crystal.

For example, according to patent document 2 (Japanese patent publication No. 2010-280562A), it is described the method that flux method and vapor phase method are combined to grow a thick gallium nitride crystal and the crystal is processed to a surface roughness Ra of 5 nm or less and to a curvature radius of warping of 2 m or larger to obtain an ingot.

Further, it is disclosed the technique of sintering gallium nitride crystal powder to produce a sputtering target (Patent document 3, WO 2016/158651 A1).

Further, as a method of direct bonding through surface activation treatment, it is disclosed the method of bonding GaN onto a supporting body using an oxide layer at room temperature ((0060) to (0061) of Patent document 4, Japanese patent publication No. 2019-003090A).

Further, it is disclosed the method that a GaN thin film is irradiated with UV laser to decompose GaN at the interface with an underlying substrate and to separate the GaN thin film from the substrate (Patent document 5, Japanese patent publication No. 2000-101139A). The method is referred to as laser lift-off method below.

### Patent Documents

(Patent document 1) Japanese patent publication No. 2005-206415A
(Patent document 2) Japanese patent publication No. 2010-280562A
(Patent document 3) WO 2016/158651 A1
(Patent document 4) Japanese patent publication No. 2019-003090A
(Patent document 5) Japanese publication No. 2000-101139A
(Patent document 6) Japanese patent publication No. 2005-263622A

### SUMMARY OF THE INVENTION

According to patent document 6 (Japanese patent publication No. 2005-263622A), the upper limit of the growth rate of GaN crystal by flux method is about 100 µm/h.

Further, according to patent document 3, in the case that gallium nitride powder is sintered and processed to provide a sputtering target and is used to form a gallium nitride thin film, it is described that the oxygen concentration of the gallium nitride thin film is higher than 1×10²⁰ cm⁻³. As the powdery gallium nitride has a large surface area, the surface is susceptible to oxidation in atmosphere, so that oxygen is discharged at the time of initiation of sputtering and a gallium nitride thin film is formed on a substrate while oxygen is easily incorporated into the inside at the same time. Thus, it is considered that it is difficult to form a uniform gallium nitride thin film having a low oxygen concentration.

If thick GaN is grown on an oriented crystal by, for example, HVPE method or flux method, to form a GaN bulk material instead of a sintered body of GaN powder, it should be possible to provide a sputtering target having a low impurity concentration, particularly low oxygen concentration and to form a gallium nitride thin film having a low oxygen concentration by sputtering treatment. However, for obtaining the crystal having a thickness which can be handled as the sputtering target, a long time is required for the growth and warping and cracks may be easily generated. It is considered that it is difficult to provide such sputtering target according to known production methods.

An object of the present invention is to obtain a thick group 13 nitride crystal layer by growing the group 13 nitride crystal layer at a high growth rate.

Further, an object of the present invention is to obtain a uniform sputtering target having a low oxygen concentration.

The present invention provides a method of growing a group 13 nitride crystal layer on an underlying substrate comprising at least a seed crystal layer, the method comprising the step of immersing said underlying substrate in a melt containing a flux to grow the group 13 nitride crystal layer two-dimensionally by flux method on a nitrogen polar surface of the seed crystal layer.

The present invention further provides a nitride semiconductor ingot comprising a group 13 nitride and having a diameter of 75 mm or larger and 200 mm or smaller and a thickness of 5 mm or larger and 50 mm or smaller.

The present invention further provides a method of producing an underlying substrate for growing a group 13 nitride crystal layer, the method comprising the steps of:
forming a seed crystal layer on a substrate;
bonding a group 13 element polar surface of the seed crystal layer onto a supporting body; and
separating the substrate from the seed crystal layer to obtain an underlying substrate comprising the seed crystal layer and the supporting body with a nitrogen polar surface of the seed crystal layer exposed.

In the case that a group 13 nitride crystal layer is grown by flux method, the present inventors tried to charge a seed crystal in a melt and to grow the group 13 nitride crystal layer on a nitrogen polar surface of the seed crystal two-dimensionally. It is thus found that the group 13 nitride crystal layer can be grown at a growth rate higher than that obtained in the case that the group 13 nitride crystal layer is grown on the group 13 element polar surface (for example, gallium polar surface).

As a result, it becomes possible to grow a thin film of the group 13 nitride crystal layer having a thickness of, for example, 5 mm or larger at a practical rate and to provide a nitride semiconductor ingot. It is proved that such nitride semiconductor ingot has characteristics excellent as, for example, a sputtering target, and that it is possible to provide the uniform target having a low oxygen concentration in particular.

Further, it is possible to produce a plurality of nitride semiconductor wafers from the thus obtained nitride semiconductor ingot by slicing, providing excellent mass-production method.

Further, according to the thus obtained nitride semiconductor ingot, it is proved that the crystal lattices are appropriately curved inside of it and that the orientation (particularly c-plane) of the crystal lattices is appropriately altered between the nitrogen polar surface and group 13 element polar surface. Since the region on the side of the growing surface resembles monocrystalline as the crystal growth is progressed in such nitride semiconductor ingot, the deformation of crystals in the nitride semiconductor wafer plane, obtained by slicing the nitride semiconductor ingot, becomes smaller. It is thus obtained a nitride semiconductor wafer having small in-plane distribution of off-angles.

### BRIEF DESCRIPTION OF THE DRAWINGS

FIG. 1 (a) shows the state that a seed crystal layer 2 is formed on a substrate 1, FIG. 1(b) shows the state that activation beams A and B are irradiated onto a surface 2a of the seed crystal layer 2 and a surface 3a of a supporting body 3, and FIG., 1(c) shows the state that the seed crystal layer 2 and supporting body 3 are directly bonded.

FIG. 2(a) shows the state that the substrate 1 is separated from the seed crystal layer 2, FIG. 2(b) shows the state that a group 13 nitride crystal layer 4 is grown on a nitrogen polar surface 2b of the seed crystal layer 2,

FIG. 2(c) shows the state that the supporting body 3 is separated from the group 13 nitride crystal layer 4, and

FIG. 2(d) shows an ingot 5 composed of the group 13 nitride crystal layer.

FIG. 3 is a plan view showing positions to be measured on a nitride semiconductor ingot 5 and on a nitride semiconductor wafer obtained by slicing the nitride semiconductor ingot.

### MODES FOR CARRYING OUT THE INVENTION

The invention will be described in detail below, appropriately referring to the drawings.

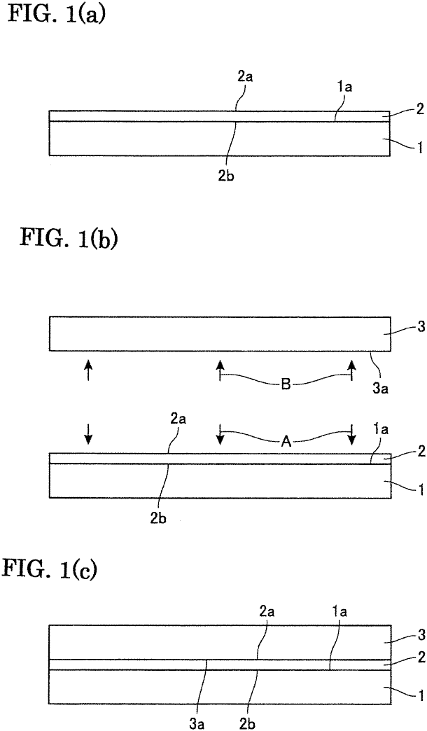

According to a preferred example, as shown in FIG. 1(a), a seed crystal layer 2 is film-formed on a surface 1a of a substrate 1. At the time, 2b is made a nitrogen polar surface, and a growing surface 2a is made a group 13 element polar surface.

Then, the seed crystal layer 2 is bonded with a separate supporting body. According to a preferred embodiment, as shown in FIG. 1(b), activation beam A is irradiated onto the group 13 element polar surface 2a of the seed crystal layer 2 to perform the surface activation. Further, activation beam is irradiated onto a surface 3a of the supporting body 3 as arrows B to perform the surface activation.

Then, as shown in FIG. 1(c), the group 13 element polar surface 2a of the seed crystal layer 2 and the activated surface 3a of the supporting body 3 are contacted and directly bonded with each other to obtain a bonded body.

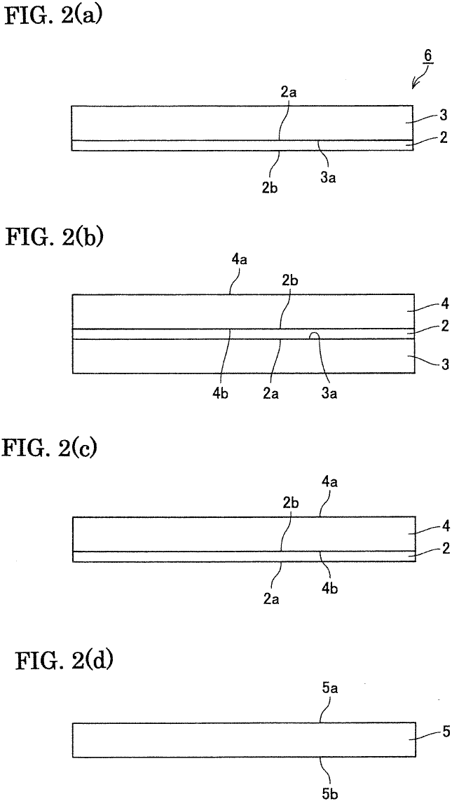

Then, as shown in FIG. 2(a), the substrate 1 is separated from the seed crystal layer 2 to obtain an underlying substrate 6. At the time, the nitrogen polar surface 2b of the seed crystal layer 2 is exposed. Then, as shown in FIG. 2(b), the group 13 nitride crystal layer 4 is grown on the nitrogen polar surface 2b of the seed crystal layer 2 by flux method.

Then, the supporting body 3 is removed from the crystal layer 4 to obtain a laminated body composed of the crystal layer 4 and seed crystal layer 2, as shown in FIG. 2(c). Then, the seed crystal layer 2 can be removed to obtain a nitride semiconductor ingot 5, as shown in FIG. 2(d). Further, 4a and 5a represent nitrogen polar surfaces, respectively, and 4b and 5b represent the group 13 element polar surfaces, respectively.

Here, according to the present invention, the group 13 nitride crystal layer is grown on the underlying substrate including at least the seed crystal layer. Here, the whole of the underlying substrate may be composed of the seed crystal layer, and preferably, the seed crystal layer is formed on the supporting body.

At the time, the group 13 nitride crystal layer is grown two-dimensionally on the nitrogen polar surface of the seed crystal layer by flux method.

Then, the group 13 nitride crystal layer is grown two-dimensionally, meaning that the crystal is grown to cover the nitrogen polar surface of the seed crystal layer so that the crystal layer is formed.

Here, according to the present invention, the group 13 nitride crystal layer is grown on the nitrogen polar surface of the seed crystal layer preferably in a thickness of 5 mm or larger, and more preferably in a thickness of 10 mm or larger. Further, although the upper limit of the thickness of the group 13 nitride crystal layer is not particularly defined, the thickness may be 50 mm or smaller on a practical viewpoint.

Further, in the case that the group 13 nitride crystal layer is grown by flux method, as the thick group 13 nitride crystal layer is directly and epitaxially grown on the nitrogen polar surface of the underlying substrate, there is possibility that the crystal is broken together with the underlying substrate. However, according to the preferred embodiment as described above, after the seed crystal layer is film-formed on the substrate, the seed crystal layer is bonded with a separate supporting body and the original substrate is then removed so that the nitrogen polar surface of the seed crystal layer on the supporting body is exposed. In the case that the thick group 13 nitride crystal layer is grown on the nitrogen polar surface by flux method, as the supporting body and crystal are separated at the interface before the crystal is broken together with the supporting body, it is possible to prevent cracks in the crystal and to obtain a thick crystal. It is thus possible to obtain a nitride semiconductor ingot having a sufficiently large thickness.

It is preferred that the seed crystal layer is provided on the substrate after a low temperature buffer layer is provided. The method of forming the buffer layer may preferably be vapor phase growth method, including metal organic chemical vapor deposition (MOCVD) method, hydride vapor phase epitaxy (HVPE) method and MBE method.

As a method for forming the seed crystal layer, vapor phase method may be listed as a preferred example, and metal organic chemical vapor deposition (MOCVD) method, hydride vapor phase epitaxy (HVPE) method, pulse excited deposition (PXD) method, MBE method and sublimation method are exemplified. metal organic chemical vapor deposition method is most preferred.

Further, in the group 13 nitride forming the seed crystal layer, the group 13 element means a group 13 element defined in the Periodic Table specified by IUPAC. Specifically, the group 13 element may be boron, gallium, aluminum, indium, thallium or the like.

The thickness of the seed crystal layer may preferably be 0.5 µm or larger and more preferably be 2 µm or larger, on the viewpoint of preventing the melt-back or disappearance during the crystal growth. Further, the thickness of the seed crystal layer may preferably be 15 µm or smaller, on the viewpoint of productivity.

Although the material of the substrate is not particularly limited, it is required to perform the crystal growth in the direction to which the group 13 element polar surface of the seed crystal layer is exposed. On such viewpoint, as the material of the substrate, sapphire, crystal orientated alumina or group 13 nitride single crystal are listed.

Further, although the material of the supporting body is not particular limited, sapphire, crystal orientated alumina and group 13 nitride single crystal are listed. Further, the thickness of the supporting body may preferably be 500 µm or larger and more preferably be 1000 µm or larger, on the viewpoint of handling.

As the method of bonding the seed crystal layer on the substrate and supporting body, direct bonding or adhesion through an adhesive may be listed.

It can be confirmed by, for example, CBED (Convergent Beam Electron Diffraction) method that the growth surface of the group 13 nitride crystal layer is the nitrogen polar surface. Specifically, electron beam is irradiated and conversed onto a sample to obtain diffraction spots of circular shape from the sample, and the diffraction spots are compared with the diffraction image (CBED pattern) calculated by simulation. The presence of the nitrogen polar surface can be thus confirmed.

In the case that the group 13 nitride crystal layer is grown on the nitrogen polar surface of the seed crystal layer, the group 13 nitride crystal layer is grown by flux method. The group 13 element of the group 13 nitride crystal layer means a group 13 element defined by the Periodic Table determined by IUPAC. Further, the group 13 nitride may specifically be GaN, AlN, InN, AlGaN or the mixed crystal thereof.

The group 13 nitride crystal layer may preferably be a single crystal. The definition of the single crystal will be described. Although it includes single crystals defined in textbooks that atoms are regularly arranged over the whole crystal, it is not meant to be limited to that and it means single crystals generally and industrially commercialized. That is, the crystal may contain some degree of defects or distortion within the crystal or impurities may be incorporated. It means that the crystal is referred to as single crystal distinguished from polycrystals (ceramics).

In the case that the group 13 nitride crystal layer is grown by flux method, the kind of the flux is not particularly limited, as far as gallium nitride crystal can be generated. According to a preferred embodiment, it may be the flux containing at least one of an alkali metal and alkaline earth metal and the flux containing sodium metal is most preferred.

As the flux, raw material substances of the metals are mixed and used. As the raw material, substance of the metal, a simple metal, alloy or metal compound may be applied. The simple metal is preferred on the viewpoint of handling.

The growth temperature and retention time during the growth of the group 13 nitride crystal layer by the flux method are not particularly limited, and may be appropriately changed depending on the composition of the flux. For example, in the case that gallium nitride crystal is grown by applying flux containing sodium or lithium, the growth temperature may be preferably be made 800 to 950° C. and more preferably be made 850 to 900° C.

According to flux method, the group 13 nitride crystal layer is grown under atmosphere containing gas containing nitrogen atom. Although the gas may be nitrogen gas, it may be ammonia. Although the pressure of the atmosphere is not particularly limited, the pressure may preferably be 10 atoms or higher and more preferably be 30 atoms, on the viewpoint of preventing the evaporation of the flux. However, as the pressure is high, the size of the system becomes large. Then, the total pressure of the atmosphere may preferably be 2000 atoms or lower and more preferably be 500 atoms or lower. Although a gas in the atmosphere other than the gas containing nitrogen atom is not particularly limited, an inert gas is preferred and argon, helium or neon is particularly preferred.

For growing the group 13 nitride crystal layer two-dimensionally on the nitrogen polar surface of the seed crystal layer by flux method, it is preferred that the underlying substrate is positioned horizontally in a crucible to thereby facilitate the supply of nitrogen over the whole surface of the seed crystal layer of the underlying substrate. Further, it is preferred to sufficiently increase the nitrogen concentration in the flux liquid. For increasing the nitrogen concentration, it is necessary to dissolve nitrogen until the nitrogen concentration of the whole liquid is super-saturated, by making the temperature of the flux liquid at a high temperature and by sufficiently agitating the flux liquid.

The method of separating the substrate and seed crystal layer and the method of separating the supporting body from the group 13 nitride crystal layer are not particularly limited and may be griding method, laser ablation method, chemical mechanical polishing method or the like, and laser lift-off method is particularly preferred.

In the case of laser lift-off method, as a laser light source, third, fourth and fifth harmonic waves of Nd: YAG laser, F₂ excimer laser, ArF excimer laser, KrF excimer laser, XeCl excimer laser, XeF excimer laser, third and fourth harmonic waves of YVO₄ laser, and third and fourth harmonic waves of YLF laser may be listed. Particularly preferred laser light source is the third harmonic wave of Nd: YAG laser, fourth harmonic wave of YAG laser, third harmonic or fourth harmonic wave of YVO₄ laser or KrF excimer laser.

The shape of irradiation of the laser may be a circle, ellipse, square or linear.

The laser profile may be shaped through a beam profiler. The laser profile may be gaussian, gaussian-like, donut or silk hat. Gaussian or silk hat are preferred.

The laser may be irradiated onto the substrate after the laser is passed through a lens, slit or aperture, for adjusting the size or energy density of the irradiated laser.

According to a preferred embodiment, pulse laser may preferably be applied to adjust the formation of a protruded part. Although the pulse width of the laser is not particularly limited, the laser of 100 fs to 200 ns may be applied. The pulse width of the laser may preferably be 200 ns or smaller and more preferably 1 ns or smaller.

Laser may be irradiated while the supporting body is heated. As the supporting body is heated, the warping is reduced so that uniform processing ca be performed within the surface of the substrate.

The nitride semiconductor ingot may be sliced to produce a plurality of nitride semiconductor wafers each having a nitrogen polar surface and group 123 element polar surface. It is thereby possible to considerably improve the productivity compared with the case that wafers are produced per a single wafer unit. The material of the nitride semiconductor wafer is same as the material of the nitride semiconductor ingot, and GaN wafer, AlN wafer, AlGaN wafer and the like are exemplified.

### Nitride Semiconductor Ingot

According to the present invention, it is possible to provide a nitride semiconductor ingot composed of a group 13 nitride, having a diameter of 75 mm or larger and 200 mm or smaller and a thickness of 5 mm or larger. Such nitride semiconductor ingot has not been provided as it is difficult to produce such nitride semiconductor ingot.

### As Sputtering Target

The nitride semiconductor ingot of the present invention has a low oxygen concentration as an impurity, and small deviation of each of oxygen concentrations in the thickness direction and in plane. That is, the oxygen concentration on the group 13 element polar surface is 0.8×10¹⁷ cm⁻³ or higher and 2×10¹⁷ cm⁻³ or lower, and the oxygen concentration on the nitrogen polar surface of the nitride semiconductor ingot is 0.5×10¹⁷ cm⁻³ or higher and 1.5×10¹⁷ cm⁻³ or lower.

All the nitride semiconductor ingots composed of prior sintered bodies have high concentrations of impurities such as oxygen. However, according to the present invention, it is possible to apply the group 13 nitride crystal layer having a high purity and to provide a sputtering target having a sufficiently low oxygen concentration.

A functional device structure can be formed on the thus obtained group 13 nitride crystal layer. Alternatively, such functional device structure can be obtained by film-formation by sputtering treatment applying the thus obtained sputtering target. The functional device structure can be applied in white light LEDs having high-luminances and high-rendering indexes, in blue-violet laser disks for high speed and high-density optical memories, and in power devices for inverters for hybrid vehicles.

### EXAMPLES

### Inventive Example 1

### Film Formation of Seed Crystal Layer

The group 13 nitride crystal layer and nitride semiconductor ingot of the present invention were produced, according to the production method shown in FIGS. 1 and 2.

Specifically, a 3-inch sapphire substrate (substrate 1) having an off angle of 0.5° was mounted on a susceptor in an MOCVD furnace (Metal organic chemical vapor deposition furnace), and the temperature of the substrate was increased to 1200° C. under hydrogen atmosphere to perform the cleaning treatment. The temperature was then lowered to 520° C., and hydrogen was applied as a carrier gas and TMG (trimethyl gallium) and ammonia were applied as raw materials to form a gallium nitride layer (buffer layer) in a thickness of 20 nm. Thereafter, nitrogen and hydrogen were applied as carrier gasses, the temperature of the substrate was increased to 1100° C., and TMG (trimethyl gallium) and ammonia were applied as raw materials to grow a GaN seed crystal layer 2 in a thickness of 3 µm. Thereafter, the temperature of the substrate with the grown GaN crystal layer was lowered to room temperature under nitrogen atmosphere, and the substrate was drawn out of the MOCVD furnace (refer to FIG. 1(a)).

### Direct Bonding

The substrate 1 with the film-formed GaN seed crystal layer 2 was drawn out and the surface of the GaN seed crystal layer 2 and supporting body 3 composed of polycrystalline alumina were bonded through direct bonding at ambient temperature (surface activation method). The surface of the supporting body 3 composed of polycrystalline alumina was polished so that the surface roughness RMS was made 1 nm. Argon beams A and B were irradiated, the polished surfaces were contacted with each other under vacuum and a load was applied to complete the direct bonding.

### Separation of Substrate 1

Laser of a short wavelength was irradiated in pulse state from the side of the substrate 1 onto the bonded body (FIG. 1(c)) directly bonded, to separate the GaN seed crystal layer 2 and substrate 1, so that it was produced the underlying substrate 6 (FIG. 2(a)) in which the GaN seed crystal layer 2 was directly bonded with the supporting body 3.

As the laser light source, the third harmonic wave (wavelength of 355 nm) of Nd:YAG laser was applied to provide the pulse laser. The repetition frequency was made 10 Hz, the pulse width was made 10 ns, light was condensed by means of a lens having a focal point of 700 mm, the distance between the lens and surface of the substrate was made 400 mm, the optical energy density during the laser lift-off was made 500 mJ/cm², and the whole of the substrate was scanned so that irradiation dots by the pulse laser were superimposed.

### Growth of Thick Film of Nitride Semiconductor Ingot by Flux Method

The thick film of the GaN crystal layer 4 was grown by flux method (FIG. 2(b)), by using the 3-inch supporting body 3 composed of polycrystalline alumina onto which the GaN seed crystal layer 2 was bonded.

Specifically, an alumina crucible was prepared, the 3-inch supporting body 3 composed of polycrystalline alumina bonded with the GaN seed crystal layer 2 was placed in the crucible, and 400 g of metal Ga and 800 g of metal Na were filled in the alumina crucible, so that the 3-inch supporting body 3 composed of polycrystalline alumina bonded with the GaN seed crystal layer 2 was immersed in a melt containing flux. Further, the alumina crucible was contained and sealed in a growth container made of a heat resistant metal. The temperature in the furnace was set to 850° C., and the pressure in the furnace was set to 4 MPa by introducing nitrogen gas. The growth container was held for 35 hours while it was rotated horizontally in a heat resistant and pressure resistant crystal growth furnace, so that the GaN crystal layer was grown on the supporting body 3 composed of polycrystalline alumina to which the GaN seed crystal layer 2 was bonded. After the temperature was cooled to room temperature, as the substrate with the grown GaN crystal layer was taken out from the alumina crucible, the GaN seed crystal layer 2 and supporting body 3 were spontaneously separated to obtain a thick film of the GaN crystal layer 4 having a diameter of 3 inches and a thickness of about 5.5 mm.

The surface and back face (separated surface) of the thick film of the separated GaN crystal layer 4 were polished by diamond abrasives for the flattening to a thickness of 5 mm and to obtain the nitride semiconductor ingot 5 having a diameter of 3 inches (FIG. 2(d)).

### Inventive Example 2

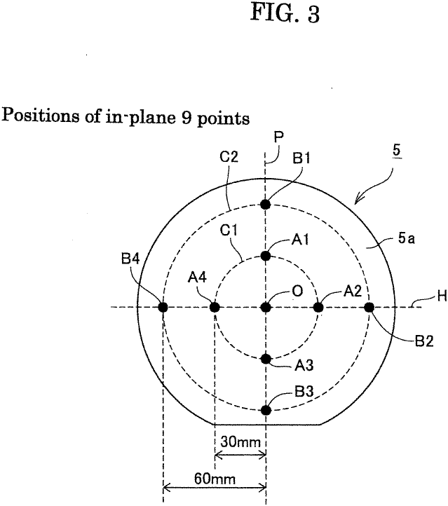

As the off angle of the 3-inch sapphire substrate used in the inventive example 1 was changed to 0.0°, 0.3°, 1°, 2° and 3° to prepare 5 kinds, and it was tried to produce the nitride semiconductor ingot according to the same method as that of the inventive example 1. The growth of the thick film of the GaN crystal layer 4 was not confirmed in the case that the off angle was 0.0° and 3°, but it was obtained the nitride semiconductor ingot having a diameter of 3 inches and thickness of 5 mm as the inventive example 1 in the case of the three kinds that the off angle was 0.3°, 1° and 2°. The three kinds of the nitride ingots were marked as #A (0.3°), #B (1°) and #C (2°), respectively, in the descending order of the off angles, and SIMS analysis was performed on each of nine points in planes of the gallium polar surface and nitrogen polar surface, respectively. The nine points in plane are set on the provision that a virtual circle C1 having a radius of 30 mm and a virtual circle C2 of a radius of 60 mm are set around the center O of the surface 5a of the nitride semiconductor ingot 5 as schematically shown in FIG. 3. Further, virtual lines P and H intersecting at right angle and passing through the center O are set. The measurement points are the center O, crossing points A1, A2, A3 and A4 of the virtual circle C1 and virtual line P and H, and crossing points B1, B2, B3 and B4 of the virtual circle C2 and virtual lines P and H. The average values of the oxygen concentrations at depths of 5 µm to 25 µm and at the in-plane 9 points were calculated, respectively, and the maximum value and minimum value were calculated, are shown in table 1.

TABLE 1

| | Maximum value of oxygen concentration at 9 points in plane of gallium polar surface (×10¹⁷ cm⁻³) | Minimum value of oxygen Concentration at 9 points in plane of gallium polar surface (×10¹⁷ cm⁻³) | Maximum value of oxygen concentration at 9 points in plane of nitrogen polar surface (×10¹⁷ cm⁻³) | Minimum value of oxygen Concentration at 9 Points in plane of nitrogen polar surface (×10¹⁷ cm⁻³) |
|---|---|---|---|---|
| #A | 2.0 | 1.8 | 1.5 | 1.3 |
| #B | 1.7 | 1.5 | 1.1 | 0.9 |
| #C | 0.9 | 0.8 | 0.6 | 0.5 |

### Inventive Example 3: Sputtering Target

A copper plate (backing plate) was heated by applying the nitride semiconductor ingot of the inventive example 2 and the nitride semiconductor ingot was bonded by applying indium metal to provide a sputtering target.

A GaN film was formed by sputtering under the conditions that the sputtering target was applied, 20 sccm of Ar, 100 sccm of N₂, a pressure of 1 Pa and an electric power of 400 W were applied, a 2-inch sapphire substrate was used as the substrate and the temperature of the substrate was set at 250° C. After the sputtering treatment, as the sapphire substrate was taken out, a GaN film having a uniform thickness of 1 µm was formed. Such sputtering treatment was repeatedly performed, and 20 counts of the GaN films were produced on the sapphire substrates and subjected to SIMS analysis. All the oxygen concentrations were proved to be 1×10¹⁷ cm⁻³_{.}

As such, in the case that the film formation was performed by using the sputtering target of the present invention, even when the sputtering target was depleted, it was possible to stably form the GaN films having the same quality.

### Inventive Example 4

It was used a 3-inch polycrystalline alumina supporting body bonded with the GaN seed crystal layer to grow a thick film of a GaN crystal layer by flux method, according to the same procedure as the inventive example 1.

When the flux method is performed, 2000 g of Ga metal and 4000 g of Na metal were filled in an alumina crucible. The alumina crucible was contained and sealed in a growth container made of a heat-resistant metal. The temperature in the furnace was made 850° C., and nitrogen gas was introduced until the pressure in the furnace reached 4 MPa. The growth container was held over 300 hours in a heat-resistant and pressure-resistant crystal growth furnace while the container was rotated horizontally, so that the GaN crystal layer was grown on the 3-inch polycrystalline alumina supporting body bonded with the GaN seed crystal layer. After it was cooled to room temperature, the substrate with the grown GaN crystal layer was taken out from the alumina crucible. It was then proved that the GaN crystal layer and polycrystalline alumina supporting body were spontaneously separated and it was obtained a thick-film of the GaN crystal layer of 3-inches and having a thickness of about 52 mm.

The surface and back face of the thick film of the separated GaN crystal layer were subjected to polishing by means of diamond abrasive grains to perform the flattening to obtain a nitride semiconductor ingot having a thickness of 50 mm. The nitride semiconductor ingot was sliced to obtain 50 sheets of 3-inch GaN wafers (nitride semiconductor wafers) each having a thickness of 0.5 mm.

3 sheets were taken out from the thus obtained GaN wafers, and the off-angle, the distribution and shape of the warping of the wafer were measured. #D was assigned to the wafer nearest to the gallium polar surface, #F was assigned to the wafer nearest to the nitrogen polar surface and #E was assigned to the wafer between #D and #F in the ingot before the slicing. The off angles were measured at the in-plane 9 points on the gallium polar surface of the GaN wafer. The measurement positions on the in-plane 9 points were selected as O, A1, A2, A3, A4, B1, B2, B3 and B4 as shown in FIG. 3. The off angle was measured by means of ″D2 Cryso″ supplied by Bruker AXS Corporation, and the difference of the maximum value and minimum value of the off angles measured at the in-plane 9 points was defined as a width of the off angles. The warping values were measured by means of “flatness tester FT-17″ supplied by NIDEK CO., LTD.. The results are shown in table 2. As shown in table 2, as it is nearer to the nitrogen polar surface, the substrate having a smaller width of the off angles was obtained.

TABLE 2

| | Average value of off angles (°) | Width of off angles (°) | Warping value SORI (µm) |
|---|---|---|---|
| #D | 0.42 | 0.80 | <±10 |
| #E | 0.37 | 0.30 | <±10 |
| #F | 0.35 | 0.10 | <±10 |

### Inventive Example 5

A GaN wafer having a larger diameter was produced, on the seed crystal composed of GaN film grown as a thin film on a substrate by sputtering treatment.

Specifically, a sapphire substrate having a diameter of 200 mm was used as the substrate, and sputtering treatment was performed by applying the sputtering target obtained in the inventive example 3. The GaN film having a thickness of 1 µm was uniformly formed.

As the judgement of the polarity was performed by CBED method, the surface of the GaN film was proved to be gallium polar surface.

This GaN film was used to grow a thick film of a GaN crystal layer by flux method. 2000 g of Ga metal and 4000 g of Na metal were filled in an alumina crucible. Further, the alumina crucible was contained and sealed in a growth container made of a heat resistant metal. The temperature in the furnace was made 850° C. and nitrogen gas was introduced until the pressure in the furnace was made 4 MPa. The growth container was held over 200 hours, while the container was rotated horizontally, in a heat resistant and pressure resistant growth furnace, so that the GaN crystal layer was grown on the sapphire substrate with the GaN film. After the temperature was lowered to room temperature, the substrate with the GaN crystal grown from the alumina crucible was taken out. The GaN crystal layer was spontaneously separated from the supporting body composed of polycrystalline alumina, so that a thick film of the GaN crystal layer having a diameter of 200 mm and thickness of about 6 mm was obtained.

As the subface and back face of the thus separated thick film of the GaN crystal layer were polished by means of diamond abrasive grains to perform the flattening, the nitride semiconductor ingot having a diameter of 200 mm and thickness of 5 mm was obtained. The nitride semiconductor ingot was sliced and the surface and back face were polished by means of diamond abrasive grains to perform the flattening, so that 3 sheets of GaN wafers each having a diameter of 200 mm and thickness of 1 mm were obtained.

1. A method of growing a group 13 nitride crystal layer, on an underlying substrate comprising a seed crystal layer comprising a group 13 nitride, said method comprising the step of immersing said underlying substrate in a melt comprising a flux to grow a group 13 nitride crystal layer two-dimensionally on a nitrogen polar surface of said seed crystal layer by flux method.

2. The method of claim 1, wherein said group 13 nitride crystal layer is grown to a thickness of 5 mm or larger.

3. The method of claim 1, comprising the steps of:
forming said seed crystal layer on a substrate;
bonding a group 13 element polar surface of said seed crystal layer to a supporting body; and
separating said substrate from said seed crystal layer to obtain said underlying substrate.

4. The method of claim 1, further comprising the step of separating said group 13 nitride crystal layer from said underlying substrate to obtain a nitride semiconductor ingot comprising said group 13 nitride crystal layer.

5. A nitride semiconductor ingot obtained by the method of claim 4.

6. A nitride semiconductor ingot comprising a group 13 nitride and having a diameter of 75 mm or larger and 200 mm or smaller and a thickness of 5 mm or larger and 50 mm or smaller.

7. A sputtering target comprising said nitride semiconductor ingot of claim 6.

8. The sputtering target of claim 7,
wherein said nitride semiconductor ingot has an oxygen concentration on a group 13 element polar surface of _{0.8}×10¹⁷ cm⁻³ or higher and 2×10¹⁷ cm⁻³ or lower and;
wherein said nitride semiconductor ingot has an oxygen concentration on a nitrogen polar surface of 0.5×10¹⁷ cm⁻³ or higher and 1.5×10¹⁷ cm⁻³ or lower.
